(19) United States
(12) Patent Application Publication
(10) Pub. No.: US 2020/0389182 A1
(43) Pub. Date: Dec. 10, 2020

(54) DATA CONVERSION METHOD AND APPARATUS

(71) Applicant: SZ DJI TECHNOLOGY CO., LTD., Shenzhen (CN)

(72) Inventors: Sijin LI, Shenzhen (CN); Yao ZHAO, Shenzhen (CN); Kang YANG, Shenzhen (CN)

(21) Appl. No.: 17/000,915

(22) Filed: Aug. 24, 2020

Related U.S. Application Data
(63) Continuation of application No. PCT/CN2018/077573, filed on Feb. 28, 2018.

(51) Int. Cl. H03M 7/24; G06F 7/544; G06F 7/485; G06F 7/487; G06F 9/30; G06N 3/063

(52) U.S. Cl. CPC H03M 7/24; G06F 7/5443; G06F 7/485; G06N 3/063; G06F 9/3001; G06F 9/30032; G06F 7/4876

(57) ABSTRACT

The present disclosure provides a data conversion method. The method includes determining a base weight value based on a bit width of a log domain of a weight and a value of a maximum weight coefficient of a first target layer of a neural network; and converting a weight coefficient in the first target layer to the log domain based on the base weight value and the bit width of the log domain of the weight.

### CROSS-REFERENCE TO RELATED APPLICATION

This application is a continuation of International Application No. PCT/CN2018/077573, filed on Feb 28, 2018, the entire content of which is incorporated herein by reference.

### TECHNICAL FIELD

The present disclosure relates to the field of data processing and, more specifically, to a data conversion method and apparatus.

### BACKGROUND

In neural network computing frameworks, floating point numbers are used for training and calculation. In the back propagation of neural networks, the calculation of gradients needs to be expressed based on the floating point numbers to ensure sufficient accuracy. In addition, the layers of the neural network's forward propagation process, especially the weight coefficients of the convolutional layer and the fully connected layer, and the output values of each layer are also expressed as floating points. For example, in the inference operation of deep convolutional neural networks, the majority of operation is concentrated in the convolution operation, and the convolution operation is consisted of a large number of multiply accumulate operations. On one hand, this arrangement consumes more hardware resources, and on the other hand, it consumes more power and bandwidth.

There are many methods for optimizing the convolution operations, one of which is to convert the floating point numbers to fixed point numbers. However, even if fixed points are used, in the accelerator of the neural network, the multiply accumulate operation based on fixed points still needs a large number of multipliers to ensure the real-time performance of the operation. Another method is to convert the data from the real domain to the logarithmic domain, and convert the multiplication operation in the multiply accumulate operation to the addition operation.

In conventional technology, the data conversion from the real domain to the logarithmic domain (log domain) needs references to the full scale range (FSR). The FSR is also referred to as the conversion reference value, which is obtained based on experience. For different networks, the FSR needs to be manually adjusted. In addition, the data conversion methods from the real domain to the log domain in conventional technology are only applicable when the data is a positive value, however, in many cases, the weight coefficient, input feature value, and output vale are negative values. The two points described above can affect the expression ability of the network, resulting in a decrease in the accuracy of the network.

### SUMMARY

One aspect of the present disclosure provides a data conversion method. The method includes determining a base weight value based on a bit width of a log domain of a weight of a first target layer of a neural network and a value of a maximum weight coefficient; and converting a weight coefficient in the first target layer to the log domain based on the base weight value and the bit width of the log domain of the weight.

Another aspect of the present disclosure provides a data conversion apparatus. The apparatus includes a processor; and a memory storing program instructions that, when executed by the processor, causing the processor to determine a base weight value based on a bit width of a log domain of a weight of a first target layer of a neural network and a value a maximum weight coefficient; and convert the weight coefficient in the first target layer to the log domain based on the base weight value and the bit width of the log domain of the weight.

### BRIEF DESCRIPTION OF THE DRAWINGS

FIG. 1 is a schematic diagram of a deep convolutional neural network.

FIG. 2 is a flowchart of a data conversion method according to an embodiment of the present disclosure.

FIG. 3 is a schematic diagram of a multiply accumulate operation according to an embodiment of the present disclosure.

FIG. 4 is a schematic diagram of a multiply accumulate operation according to another embodiment of the present disclosure.

FIGS. 5A, 5B and 5C are schematic diagrams of several cases of merge preprocessing according to embodiments of the present disclosure; and FIG. 5D is a schematic diagram of a layer connection method of a batch normalization (BN) layer after a convolutional layer.

FIG. 6 is a schematic block diagram of a data conversion apparatus according to an embodiment of the present disclosure.

FIG. 7 is a schematic block diagram of a data conversion apparatus according to another embodiment of the present disclosure.

FIG. 8 is a schematic block diagram of a data conversion apparatus according to another embodiment of the present disclosure.

FIG. 9 is a schematic block diagram of a data conversion apparatus according to another embodiment of the present disclosure.

### DETAILED DESCRIPTION OF THE EMBODIMENTS

Exemplary embodiments of the present disclosure will be described with reference to the accompanying drawings.

Unless otherwise defined, all the technical and scientific terms used in the present disclosure have the same or similar meanings as generally understood by one of ordinary skill in the art. As described in the present disclosure, the terms used in the specification of the present disclosure are intended to describe example embodiments, instead of limiting the present disclosure.

The concepts and the related technologies related to the exemplary embodiments of the present disclosure will be described first. A neural network, such as a deep convolutional neural network (DCNN) will be described below.

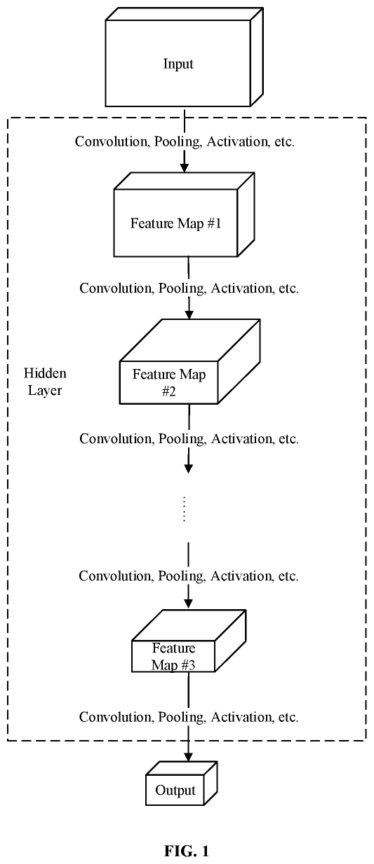

FIG. 1 is a schematic diagram of a deep convolutional neural network (DCNN).

An output feature value (output by an output layer and referred to as an output value in the present disclosure) is obtained after a hidden layer performs operations such as convolution, transposed convolution or deconvolution, batch normalization (BN), scale, fully connected, concatenation, pooling, element-wise addition, and activation on an input feature value (input from an input layer) of the DCNN. The operations that may be related in the hidden layer of the neural network in the embodiments of the present disclosure are not limited to the operations described above.

The hidden layer of the DCNN can include multiple cascading layers. The input of each layer may be the output of the upper layer, which is a feature map. Each layer can perform one or more operations described above on one or more sets of input feature maps to obtain the output of the layer. The output of each layer is also a feature map. Generally, each layer is named after the function implemented, for example, a layer that implements the convolution operation may be called the convolution layer. In addition, the hidden layer can also include a transposed convolution, a BN layer, a scale layer, a pooling layer, a fully connected layer, a concatenation layer, an element-wise addition layer, an activation layer, etc., which are not completely listed herein. The specific operation process of the layers, reference may be made to conventional technology, which will not be repeated in the present disclosure.

It can be understood that each layer (including the input layer and the output layer) may have one input and/or one output, or multiple inputs and/or multiple outputs. In the classification and detection tasks in the visual field, the width and height of the feature map are generally decreasing layer by layer (for example, the width and height of the input, feature map #1, feature map #2, feature map #3, and output layer shown in FIG. 1 are decreasing layer by layer). In the semantic segmentation task, after the width and height of the feature map decrease to a certain depth, it may be increased layer by layer through transposed convolution operations or upsampling operations.

Generally, the convolution layer will be followed by an activation layer. Common activation layers include a rectified linear unit (ReLU) layer, a sigmoid (S) layer, a tanh layer, etc. After the BN layer is proposed, more and more neural networks will first perform a BN processing, and then perform the activation calculation.

The layers that need more weight parameters for operations are the convolution layer, the fully connected layer, the transposed convolution layer, and the BN layer.

When the data is expressed in the real domain, the data is expressed by the value of the data itself.

When the data is expressed in the log domain, the data is expressed in terms of the log value of the absolute value of the data (for example, take the log value of 2 as the absolute value of the data).

The present disclosure provides a data conversion method. The method includes an offline part and an online part. The offline part may be to determine a base weight value of the weight coefficient corresponding to the log domain before the operation of the neural network or outside the operation, and convert the weight coefficient to the log domain. At the same time, a base output value corresponding to the log domain of the output value of each can also be determined. The online part may be the specific calculation process of the neural network, that is, the process of obtaining the output value.

The process of the neuron multiplication operation after the data is converted from the real domain to the log domain will be described first. For example, the weight coefficient w may be 0.25, and the input feature value in the real domain x may be 128. In conventional real domain calculation, the output value in the real domain y may be w*x=0.25*128=32. This multiplication operation needs a multiplier to complete, which requires high hardware requirements. In the log domain, the weight coefficient w=0.25=2⁻² can be expressed as \tilde{w}=−2, and the input feature value x=128=27 can be expressed as \tilde{x}=7. The above multiplication operation can be converted into an addition operation in the log domain. The output value y=2⁻²*2⁷=2⁽⁻²⁺⁷⁾=25, that is, the output value y can be expressed as \tilde{y}=5 in the log domain. Converting the output value in the log domain to the real domain only requires a shift operation, where the output value y=1<<(−2+7)=32. As such, the multiplication operation only requires addition and shift operations to obtain the result.

In the above process, the weight coefficient of the log domain \tilde{w}=−2. In order to simplify the expression of the data in the log domain, a conventional method proposes to obtain the FSR based on experience. For example, FSR=10 and the bit width is 3, then the range corresponding to the log domain of the data may be {0, 3, 4, 5, 6, 7, 8, 9}, where −2 may correspond to a certain value in the range, thereby avoiding the weight coefficient of the log domain being a negative value.

In conventional technology, the range of the FSR needs to be adjusted under different networks. In addition, the conventional method for converting data from the real domain to the log domain is only application to cases where the real domain data is a positive value, but the weight coefficient, input feature value, and output value are negative values in many cases. The two points described above affect the expression ability of the network, thereby causing the accuracy of the neural network (hereinafter referred to as the network) to decrease.

In the present disclosure, the bit width of the log domain of the weight of a given weight coefficient may be BW_W, the input value log bit width of the input feature value may be BW_X, and the output value log bit width of the output value may be BW_Y.

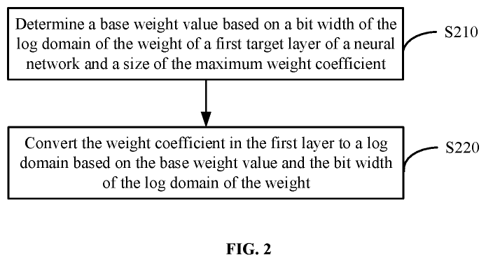

FIG. 2 is a flowchart of a data conversion method 200 according to an embodiment of the present disclosure. The method will be described in detail below.

S210, determining a base weight value based on a bit width of the log domain of the weight of a first target layer of a neural network and a value of the maximum weight coefficient.

S220, converting the weight coefficient in the first layer to a log domain based on the base weight value and the bit width of the log domain of the weight.

In the data conversion method of the present disclosure, the base weight value may be determined based on the bit width of the log domain of the weight and the value of the maximum weight coefficient, and the weight coefficient may be converted to the log domain based on the base weight value and the bit width of the log domain of the weight. As such, the base weight value of the weight coefficient is not based on experience, but is determined based on the bit width of the log domain of the weight and the maximum weight coefficient, which can improve the expression ability of the network and the accuracy of the network.

It should be understood that the maximum weight coefficient may be regarded as the weight reference value of the weight coefficient, which can be denoted as RW. In the embodiments of the present disclosure, the weight reference value may be the maximum weight coefficient after removing the abnormal value, and it may also be a selected value other than the maximum weight coefficient, which is not limited in the present disclosure. For any layer in the neural network, such as the first target layer, the base weight value of this layer can be determined by the maximum weight coefficient of the first target layer. The base weight value may be denoted as BASE_W. It should be noted that the base weight value in various embodiments of the present disclosure may be calculated based on the accuracy requirements. The base weight value may be an integer, a positive number, a negative number, and it may include decimal points. The weight reference value may be obtained based on Formula 1.

BASE_W=ceil (|log₂|RW|)−2^{BW-W-1}+1 (Formula 1)

where ceil( ) may be a round-up function.

By determining the base weight value BASE_W based on Formula (1), the larger weight coefficient can have higher accuracy when converting the weight coefficient to the log domain.

It should be understood that the term 2^{BW-W-1} in Formula (1) is based on the case where the weight coefficient converted to the log domain includes a sign bit. When the weight coefficient of the log domain does not include the sign bit, the term may be 2^{BW-W}. In the embodiments of the present disclosure, the method of determining the BASE_W is not limited to Formula (1), and the BASE_W may be determined based on other principles and through other formulas.

It should also be understood that the term in S2002, the weight coefficients in the first target layer can be converted into the log domain, or only a part of the weight coefficients in the first target layer can be converted into the log domain, which is not limited in the embodiments of the present disclosure.

In some embodiments, converting the weight coefficient in the first layer to the log domain based on the base weight value and the bit width of the log domain of the weight may include converting the weight coefficient to the log domain based on the base weight value, the bit width of the log domain of the weight, and the value of the weight coefficient.

In the embodiments of the present disclosure, the bit width of the log domain of the weight may include a sign bit, and the sign of the weight coefficient in the log domain may be the same as the sign of the weight coefficient in the real domain. In conventional technology, when the data is converted to the log domain, if the data value is negative, the data is uniformly converted to the log domain value corresponding to the zero value in the real domain. In the embodiments of the present disclosure, the positive and negative signs of the weight coefficients are retained, which can improve the accuracy of the network.

More specifically, conversion of the weight parameters to the log domain may be calculated based on Formula (2).

$$\tilde{w} = \{ \begin{matrix}- {2}^{BW\_W - 1} , & 0 \leq \vert w \vert < {2}^{BASE\_W - 1} \\ \begin{matrix}sign ( w ) * Clip \\ ( \begin{matrix}Round ( {log}_{2} \vert w \vert ) - \\ BASE\_W , 0 , {2}^{BW\_W - 1} - 1 , - {2}^{BW\_W - 1}\end{matrix} ) ,\end{matrix} & otherwise\end{matrix} \qquad Formula ( 2 )$$

where sign( ) may be expressed as the following formula:

$$sign ( z ) = \{ \begin{matrix}1 , & z > 0 \\ - 1 , & z < 0\end{matrix} \qquad Formula ( 3 )$$

and Round( ) may be expressed as the following formula:

Round(z)=int(z+0.5) Formula (4)

where int may be the rounding function.

Clip( ) may be expressed as the following formula:

$$Clip ( z , min , max , ZeroVal ) = \{ \begin{matrix}ZeroVal , & z \leq min \\ max , & z \geq max \\ z , & otherwise\end{matrix} \qquad Formula ( 5 )$$

Therefore, the weight coefficient w of the real domain can be expressed by BASE_W and the weight coefficient of the log domain \tilde{w}.

In a specific example, for the weight coefficient of the first target layer, the bit width of the log domain of the weight may be BW_W=4, and the base weight reference value may be RW=64. As such, the base weight value BASE_W=ceil(log2|64|)-24-1+1=6-8+1=−1, and the range of value of \tilde{w} may be \tilde{w}={0, ±1, ±2, ±3, ±4, ±5, ±6, ±7, −8}, where −8 may represent zero in the real domain, and the sign may represent the positive and negative of the real domain.

In the above example, the bit width of the log domain of the weight BW_W includes all integer bits. For example, after considering the base weight value BASE_W, ±(0-128) can be achieved with a 4-bit bit width, that is, a weight coefficient value of±(0, 1, 2, 4, 8, 16, 32, 64, and 128), where the 1 bit is the sign bit. The bit width of the log domain of the weight BW_W in the embodiments of the present disclosure may also include decimal points. For example, after considering the base weight value BASE_W, ±(0-2^{3.5}) can be expressed by a 4-bit bit width (two integers and one decimal point), that is, ±(0, 2⁰, 2^{0.5}, 2¹, 2^{1.5}, 2², 2^{2.5}, 2³, and 2^{3.5}), where the 1 bit is the sign bit.

In the embodiments of the present disclosure, the sign bit may not be included in the bit width of the log domain of the weight. For example, when the weight coefficients are all positive values, the sign bit may not be included in the bit width of the log domain of the weight.

The above is the process of converting the weight coefficients in the log domain in the offline part. The offline part can also include determining the base output value corresponding to the log domain, but this may not be necessary in certain scenarios. That is, in practical applications, it may only be necessary to convert the weight coefficients to the log domain, but not to convert the output value to the log domain. As such, this process may be omitted. Correspondingly, the method 200 may further include determining the base output value based on the bit width of the log domain of the output value of the first target layer and the value of a reference output value RY. This process may be performed after S220, before S210, or at the same time when S210 to S220 is performed, which is not limited in the embodiments of the present disclosure.

In some embodiments, the reference output value RY may be determined by calculating the maximum output value of each input sample in the first target layer in a plurality of input samples, and selecting the reference output value RY from a plurality of maximum output values. More specifically, selecting the reference output value RY from multiple maximum output values may include sorting the plurality of maximum output values, and selecting the reference output value RY from the plurality of maximum output values based on a predetermined selection parameter.

More specifically, sorting the multiple maximum output values (e.g., M maximum output values), may include sorting in an ascending order or a descending order, or sorting based on a predetermined rule. After sorting, a maximum output value may be selected from the M maximum output values based on the predetermined selection parameter (e.g., the selection parameter may be the value of a specific position after sorting) as the reference output value RY.

In a specific example, M maximum output values may be arranged in ascending order, the selection parameter may be a, and axM^{th} maximum output value may be selected as the reference output value RY, where a may be greater than or equal to zero, and less than or equal to one. In some embodiments, the selection parameter a may be the maximum value (i.e., a=1) and the next largest value. The method of selecting the reference output value RY is not limited in the present disclosure.

It should be understood that the reference output value RY can also be determined by other methods, which is not limited in the embodiments of the present disclosure.

More specifically, the base output value BASE_Y based on the bit width of the log domain of the output value BW_Y and the reference output value RY may be determined by using the following formula:

BASE_Y=ceil (log₂|RY|)−2^{BW_Y-1}+1 Formula (6)

It should be understood that in the embodiments of the present disclosure, the determination of the BASE_Y is not limited to Formula (6), and the BASE_Y may be determined based on other principles and through other formulas.

In the embodiments of the present disclosure, both the weight coefficient and the output value can be expressed in the form of difference values based on the base value to ensure that each difference value is a positive number, and only the base value may be a negative value. As such, each weight coefficient and output value can save 1-bit bit width such that the storage overhead can be reduced. For the huge data scale of the neural network, this can produce significant gain in bandwidth.

For the online part, a convolution operation, a fully connected operation, or another layer of neural network operation may be expressed by the multiply accumulate operation in Formula (7).

y=Σᵢ₌₀^{kc}Σⱼ₌₀^{kh}Σₖ₌₀^{kw} xᵢⱼₖ*wᵢⱼₖ Formula (7)

Where kc may be the number of input feature value channels, kh may be the height of the convolution kernel, kw may be the width of the convolution kernel, x may be the input feature value, w may be the weight coefficient, and y may be the output value.

Correspondingly, after converting the weight coefficient in the first target layer to the log domain based on the base weight value and the bit width of the log domain of the weight in S220, the method 200 may further include determining the input feature value of the first target layer. By using the shift operation, the input feature value and the log domain weight coefficient may be multiplied and accumulated to obtain the output value of the first target layer in the real domain.

More specifically, each embodiment of the present disclosure can obtain the real domain output value through addition operation combined with shift operation. In the case where the input feature values are the input feature value in the real domain and the input feature value in the log domain, respectively, the embodiments of the present application may have different processing methods.

In some embodiments, the input feature value may be the input feature value in the real domain. Using the shift operation to multiply and accumulate the input feature value and the log domain weight coefficient to obtain the output value of the first target layer in the real domain may include obtaining the multiply accumulate value through a first shift operation, and multiply and accumulate the input feature value in the real domain and the log domain weight coefficient; and performing a second shift operation on the multiply accumulate value to obtain the output value of the first target layer in the real domain.

More specifically, the input feature values (e.g., the input feature value of the first layer of the neural network) of some embodiments of the present disclosure may not be converted to the log domain since converting the input feature value to the log domain may cause a loss of detail. Therefore, the input feature value may remain to be expressed in the real domain. The weight coefficient w may have been converted to the log domain in the offline part, expressed as BASE_W and a non-negative \tilde{w}. The base output value BASE_Y of the output value may have been determined in the offline part.

More specifically, in some embodiments, the input feature value can be a fixed-point number in the real domain, and the weight coefficient w may already be converted to the log domain in the offline part, expressed as BASE_W and the non-negative \tilde{w}. Assuming that the fixed-point format of the input feature value is QA.B, and fixed-point format of the output value may be QC.D, where A and C may be the integer bit width, and B and D may be the decimal bit width.

Therefore, perfuming the second shift operation on the multiply accumulate value to obtain the output value of the first target layer in the real domain may include performing shift operation on the multiply accumulate value to obtain the output value of the first target layer in the real domain based on the decimal bit width of the input feature value in the real domain and the decimal bit width of the output value in the real domain. Since the weight coefficient may be the value of the log domain expressed by the BASE_W and the non-negative \tilde{w}, the output value of the first target layer in the real domain may be obtained by performing shift operation on the multiply accumulate value based on the decimal bit width of the input feature value in the real domain, the decimal bit width of the output value in the real domain, and the base weight value.

More specifically, the multiply accumulate operation in Formula (7) can be simplified to Formula (8).

y=bitshift(yₛᵤₘ,B-BASE_W-D) Formula (8)

where bitshift(yₛᵤₘ,B-BASE_W-D) in Formula (8) may be the second shift operation, which can be expressed by Formula (9).

$$bitshift ( z , k ) = \{ \begin{matrix}z • k , & k < 0 \\ z • k , & k \geq 0\end{matrix} \qquad Formula ( 9 )$$

yₛᵤₘ may be calculated using Formula (10) and Formula (11).

yₛᵤₘ=Σᵢ₌₀^{kc} Σⱼ₌₀^{kh} Σₖ₌₀^{kw} sign (\tilde{w}ᵢⱼₖ)*leftshift(xᵢⱼₖ, |\tilde{w}ᵢⱼₖ|, −2^{BW_W-1}) Formula (10)

where leftshift(xᵢⱼₖ, |\tilde{w}ᵢⱼₖ|, −2^{BW_W-1}) in Formula (10) may be the first shift operation, which can be expressed by Formula (11).

$$leftshift ( z , k , ZeroVal ) = \{ \begin{matrix}0 , & k = ZeroVal \\ z • k , & otherwise\end{matrix} \qquad Formula ( 11 )$$

The output value y of the real domain in the fixed-point format of QC.D may be obtained by using Formula (8) through Formula (11).

In a specific example, assuming the fixed-point format of the input feature value is Q7.0 and the input feature value in the real domain are x1=4, x2=8, and x3=16. The fixed-point format of the output value may be Q4.3. The bit width of the log domain of the weight may be BW_W=4, and the base weight values may be BASE_W=−7, \tilde{w}1=−1, \tilde{w}2=2, and \tilde{w}3=−8. Then the output value y of the real domain may be y=(−(4<<1)+8<<2)>>(0−(−7)−3)=(−8+32)>>4=1, where <<may be a left shit, and>> may be a right shift. Since \tilde{w}3=−8 may represent zero in the real domain, x3*w3 does not need to be calculated.

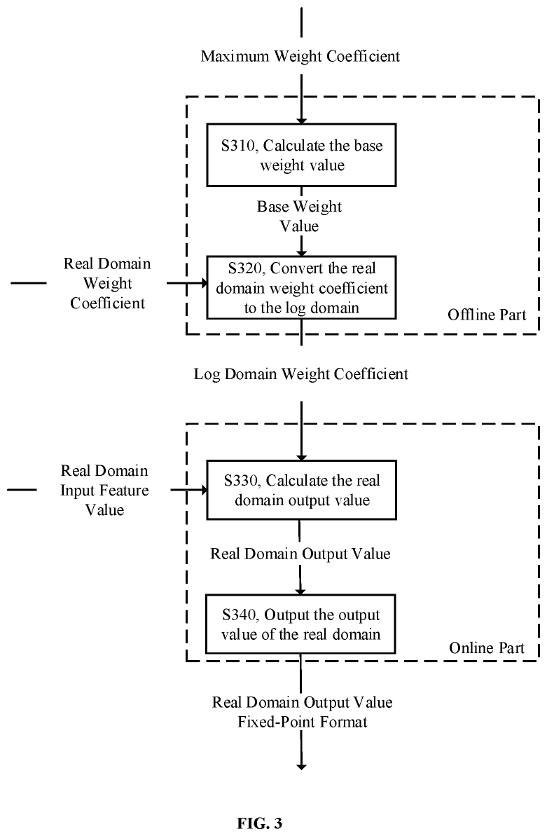

FIG. 3 is a schematic diagram of a multiply accumulate operation 300 according to an embodiment of the present disclosure. In particular, S310 and S320 are implemented in the offline part, and S330 and S340 are implemented in the online part. The method will be described in detail below.

S310, calculating the base weight value based on the maximum weight coefficient. More specifically, the base weight value may be determined based on the bit width of the log domain of the weight of the first target layer and the value of the maximum weight coefficient.

S320, converting the weight coefficient of the real domain to the log domain based on the base weight value to obtain the weight coefficient in the log domain. More specifically, the weight coefficient of the real domain in the first target layer may be converted to the log domain based on the base weight value and the bit width of the log domain of the weight to obtain the weight coefficient of the log domain.

S330, calculating the output value in the real domain based on the input feature value in the real domain and the weight coefficient of the log domain. More specifically, through the first shift operation, the input feature value in the real domain and the weight coefficient of the log domain may be multiplied and accumulated to obtain the multiply accumulate value; and a second shift operation may be performed on the multiply accumulate value to obtain the output value of the first target layer in the real domain.

S340, outputting the output value in the real domain, which can be the output value in the fixed-point format of the real domain.

If subsequent calculations need to convert the output value y of the real domain to the log domain, the method may further include the process of converting the output value in the real domain to the log domain. More specifically, after performing the shift operation on the multiply accumulate value to obtain the output value in the real domain of the target layer based on the decimal bit width of the input feature value in the real domain, the decimal bit width of the output value in the real domain, and the base weight value, the method may further include converting the output value in the real domain to the log domain based on the base output value, the bit width of the log domain of the output value, and the value of the output value in the real domain. In some embodiments, the bit width of the log domain of the output value may include a sign bit. The sign of the output value in the log domain may be the same sign of the output value in the real domain.

More specifically, the conversion of the output value to the log domain may be calculated by using Formula (12), which is similar to Formula (2).

$$\tilde{y} = \{ \begin{matrix}- {2}^{BW\_Y - 1} , & 0 \leq \vert y \vert < {2}^{BASE\_Y - 1} \\ \begin{matrix}sign ( y ) * Clip \\ ( \begin{matrix}Round ( {log}_{2} \vert y \vert ) - \\ BASE\_Y , 0 , {2}^{BW\_Y - 1} - 1 , - {2}^{BW\_Y - 1}\end{matrix} ) ,\end{matrix} & otherwise\end{matrix} \qquad Formula ( 12 )$$

In some embodiments, performing the second shift operation on the multiply accumulate value to obtain the output value of the first target layer in the real domain may include performing the shift operation on the multiply accumulate value to obtain the output value of the first target layer in the real domain based on the base weight value and the base output vale.

More specifically, the multiply accumulate operation of Formula (7) may be simplified to Formula (13).

y=bitshift (yₛᵤₘ, BASE_Y-BASE_W-1) Formula (13)

where −1 in Formula (13) is to reserve one more number, such that this number can be regarded as the fixed-point number with one decimal point.

For details related to bitshift( ) and Yₛᵤₘ, reference may be made to Formula (9) to Formula (11), where bitshifi(yₛᵤₘ, BASE_Y_BASE _W-1) in Formula (13) may be the second shift operation.

The output value y of the real domain here may be the output value in the real domain after the base output value BASE_Y has been considered. The output value y of the real domain can be converted to the log domain. More specifically, after performing the shift operation on the multiply accumulate value to obtain the output value in the real domain of the target layer based on the base weight value and the base output value, the method 200 may further include converting the output value in the real domain to the log domain based on the bit width of the log domain of the output value and the value of the output value in the real domain. In some embodiments, the output value may include a sign bit in the bit width of the log domain of the output value. The sign of the output value in the log domain may be the same as the sign of the output value in the real domain.

More specifically, the output value y of the real domain may be converted to the log domain by using Formula (14).

$$\tilde{y} = \{ \begin{matrix}- {2}^{BW\_Y - 1} , & 0 \leq \vert y \vert < {2}^{- 1} \\ \begin{matrix}sign ( y ) * Clip \\ ( \begin{matrix}Round ( {log}_{2} \vert y \vert ) , \\ 0 , {2}^{BW\_Y - 1} - 1 , - {2}^{BW\_Y - 1}\end{matrix} ) ,\end{matrix} & otherwise\end{matrix} \qquad Formula ( 14 )$$

For details related to sign( ), Round( ), and Clip( ), reference may be made to Formula (3) to Formula (11).

In some embodiments, the input feature value may be the input feature input in the log domain. Using the shift operation to perform the multiply accumulate operation on the input feature value and the log domain weight coefficient to obtain the output value of the first target layer in the real domain may include obtaining the multiply accumulate value by using a third shift operation to perform the multiply accumulate operation on the input feature value and the log domain weight coefficient; and performing a fourth shift operation on the multiply accumulate value to obtain the output value of the first target layer in the real domain. This technical solution is applicable to the middle layer of the neural network, where the input feature value of the middle layer may be the output value of the previous layer, which has been converted to the log domain.

It should be understood that the base output value of the output vale of the upper layer of the first target layer (the middle layer of the neural network) described above may be regarded as a base input value of the input feature value of the first target layer, which can be denoted as BASE_X, the base output value of the output value of the first target layer may be BASE_Y, and the base weight value of the weight coefficient of the first target layer may be BASE_W.

More specifically, performing the fourth shift operation on the multiply accumulate value to obtain the output value of the first target layer in the real domain may include performing the shift operation on the multiply accumulate operation to obtain the output value of the first target layer in the real domain based on the base input value, the base output value, and the base weight value.

More specifically, Formula (7) may be simplified to Formula (15).

y=bitshifi(yₛᵤₘ,BASE_Y-BASE_W-BASE_X-1) Formula (15)

For details of bitshift( ), reference may be made to Formula (9). In some embodiments, the bitshift(yₛᵤₘ, BASE _Y-BASE _W-BASE _X-1) in Formula (15) may be the fourth shift operation. Further, yₛᵤₘ may be calculated by using Formula (16) and Formula (17).

$$\begin{matrix}{y}_{sum} = {\sum }_{i = 0}^{kc} {\sum }_{j = 0}^{kh} {\sum }_{k = 0}^{kw} sign ( {\tilde{w}}_{ijk} ) * sign ( {\tilde{x}}_{ijk} ) * leftshiftwx ( \vert {\tilde{w}}_{ijk} \vert , \vert {\tilde{x}}_{ijk} \vert , - {2}^{BW\_W - 1} , - {2}^{BW\_X - 1} ) & Formula ( 16 ) \\ leftshiftwx ( z , k , ZZeroVal , KZeroVal ) = \{ \begin{matrix}0 , & z = ZZeroVal or k = KZeroVal \\ 1 ≪ z + k , & otherwise\end{matrix} & Formula ( 17 )\end{matrix}$$

where leftshiftwx(|\tilde{w}ᵢⱼₖ|, |\tilde{x}ᵢⱼₖ|, −2^{BW_W-1}, −2^{BW_X-1}) in Formula (16) may be the third shift operation.

In some embodiments, assuming the input feature value of the log domain may be \tilde{x}1=2, \tilde{x}2=5, respectively, the base output value BASE_X=2, the bit width of the log domain of the weight BW_W=4, the base weight value BASE_W=−7, \tilde{w}1=−1, \tilde{w}2=0, the bit width of the log domain of the out value BW_Y=4, and the base output value BASE_Y=3. Then the output value y of the real domain may be y=[−(1<<(1+2))+(1<<(0+5))]>>3−(−7)-2-1=[−8+64]>>7=0.

The output value y may be converted into the log domain (\tilde{y}=8), or it may not be converted into the log domain, which is not limited in the embodiments of the present disclosure.

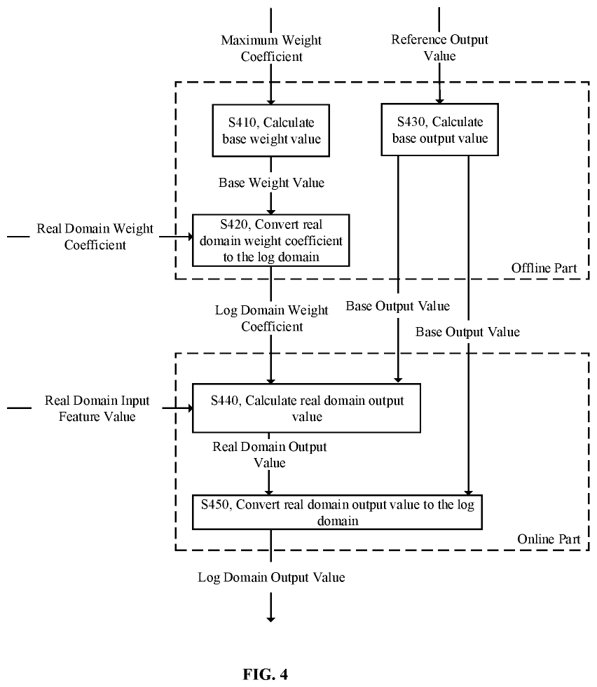

FIG. 4 is a schematic diagram of a multiply accumulate operation 400 according to another embodiment of the present disclosure. In particular, S410 and S430 are implemented in the offline part, and S440 and S450 are implemented in the online part. The method will be described in detail below.

S410, calculating the base weight value based on the maximum weight coefficient. More specifically, the base weight value may be determined based on the bit width of the log domain of the weight of the first target layer and the value of the maximum weight coefficient.

S420, converting the weight coefficient of the real domain to the log domain based on the base weight value to obtain the weight coefficient in the log domain. More specifically, the weight coefficient of the real domain in the first target layer may be converted to the log domain based on the base weight value and the bit width of the log domain of the weight to obtain the weight coefficient of the log domain

S430, calculating the base output value based on the reference output value. More specifically, the base output value may be determined based on the bit width of the log domain of the output value of the first target layer and the value of the reference output value.

S440, calculating the output value in the real domain based on the input feature value in the real domain, the weight coefficient of the log domain, and the output reference value.

S450, converting the output value in the real domain to the log domain based on the value of the output value in the real domain and the output reference value. Based on the bit width of the log domain of the output value, the base output value, and the value of the output value in the real domain, the output value in the real domain may be converted to the log domain.

In the embodiments of the present disclosure, log₂( ) can be achieved by removing the sign bit, from the high bit to the low bit, the first position corresponding to a none-zero value. The two multiplication operations of sign(\tilde{w}ᵢⱼₖ)*sign(\tilde{x}ᵢⱼₖ)*leftshiftwx( ) in hardware design are connected by XOR and sign bit stitching, there is, no multiplier is needed.

It should be understood that an embodiment of the present disclosure further provides a data conversion method. The method may include determining the input feature value of the first target layer of the neural network; and performing the multiply accumulate operation on the input feature value and the weight coefficient of the log domain by using the shift operation to obtain the output value of the first target layer in the real domain. Determining the weight coefficient of the log domain may be achieved using a conventional method or the method of the embodiment of the present disclosure, which is not limited in the embodiments of the present disclosure.

The first target layer in the embodiments of the present disclosure may include one or a combined layer of at least two of a convolution layer, a transposed convolution layer, a BN layer, a scale layer, a pooling layer, a fully connected layer, a concatenation layer, an element-wise addition layer, and an activation layer. That is, the data conversion method 200 of the embodiment of the present disclosure may be applied to any layer or multiple layers of the hidden layer of the neural network.

Corresponding to the case where the first target layer includes two or more combined layers, the data conversion method 200 may further include performing merge preprocessing on two or more layers of the neural network to obtain the first target layer formed after the merger. This processing can be considered as a preprocessing part of the data fixed-point method.

After the training phase of the neural network is completed, the parameters of the convolution layer, the BN layer, and the scale layer in the inference stage may be fixed. Through calculation and deduction, it should be clear that the parameters of the BN layer and the scale layer can be merged into the parameters of the convolution layer, such that an intellectual property core (IP core) of the neural network does not need to design special circuits for the BN layer and the scale layer.

In early neural networks, the convolution layer was followed by the activation layer. In order to prevent the network from overfitting, accelerating the convergence speed, and enhancing the generalization ability of the network, etc., the BN layer can be introduced after the convolution layer and before the activation layer. The input of the BN layer may include B={x₁, . . ., xₘ}={xᵢ} and parameters γ and β, where xᵢ may be both the output of the convolution layer and the input of the BN layer. The parameters γ and β may be calculated during the training phase and may be constant during the interference phase. The output of the BN layer may be {yᵢ=BN_{γ,β}(xᵢ)}, where

$${y}_{i} ← γ {\hat{x}}_{i} + β ≡ {BN}_{γ , β} ( {x}_{i} )$$

$${\hat{x}}_{i} ← \frac{{x}_{i} - {µ}_{B}}{\sqrt{{σ}_{B}^{2} + ɛ}}$$

$${µ}_{B} ← \frac{1}{m} {\sum }_{i = 1}^{m} {x}_{i}$$

$${σ}_{B}^{2} ← \frac{1}{m} {\sum }_{i = 1}^{m} {( {x}_{i} - {µ}_{B} )}^{2}$$

Therefore, the calculation of \hat{x}ᵢ and yᵢ may be simplified as:

$${\hat{x}}_{i} ← \frac{{x}_{i} - {µ}_{B}}{α}$$

$${y}_{i} = γ \frac{{x}_{i} - {µ}_{B}}{α} + β = \frac{γ}{α} {x}_{i} + β - \frac{γ \times {µ}_{B}}{α} = a {x}_{i} + b$$

where xᵢ may be the output of the convolution layer. Let X be the input of the convolution layer, W be the matrix of the weight coefficients, and \tilde{b} be the offset value, such that

xᵢWX+b̅

yᵢ=aWX+b̅+b=\tilde{W}X+\tilde{b}

As such, the merge of the convolution layer and the BN layer is completed.

Since the scale layer needs to be calculated, in view of the merger of the BN layer and the convolution layer, the scale may also be merged with the convolution layer. Under the Caffe framework, the output of the BN layer is \hat{x}ᵢ. Therefore, the neural network designed based on the Caffe framework will generally add the scale layer after the BN layer to achieve complete normalization.

Therefore, performing merge preprocessing on two or more layers of the neural network to obtain the first target layer formed after the merger may include merging and preprocessing the convolution layer and the BN layer of the neural network to obtain the first target layer; or, merging and preprocessing the convolution layer and the scale layer to obtain the first target layer; or, merging and preprocessing the convolution layer, BN layer, and the scale layer of the neural network to obtain the first target layer.

Correspondingly, in the embodiments of the present disclosure, the maximum weight coefficient may be the maximum value of the weight coefficient of the first target layer formed by merging and preprocessing two or more layers of the neural network.

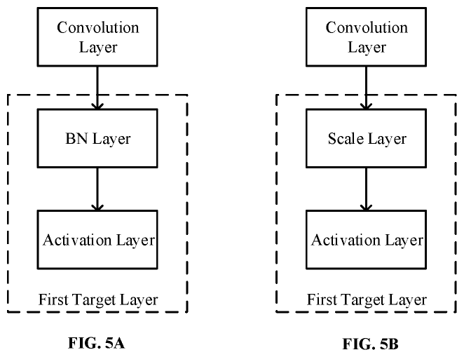

FIGS. 5A, 5B and 5C are schematic diagrams of several cases of merge preprocessing according to embodiments of the present disclosure; and FIG. 5D is the simplest layer connection method in which the convolution layer is followed by the BN layer.

As shown in FIG. 5A, before the merge preprocessing, the convolution layer is followed by the BN layer, and then the activation layer. The convolution layer and the BN layer are merged into the first target layer, followed by the activation layer, resulting in a two-layer structure similar to FIG. 5D.

It should be understood that some IP cores may support the processing of the scale layer, such that the merger of the convolution layer and the BN layer in the merge preprocessing can be replaced by the merger of the convolution layer and the scale layer. As shown in FIG. 5B, ore the merge preprocessing, the convolution layer is followed by the scale layer, and then the activation layer. The convolution layer and the scale layer are merged into the first target layer, followed by the activation layer, resulting in a two-layer structure similar to FIG. 5D.

As shown in FIG. 5C, ore the merge preprocessing, the convolution layer is followed by the BN layer, the scale layer, and then the activation layer. The convolution layer, the BN layer, and the scale layer are merged into the first target layer, followed by the activation layer, resulting in a two-layer structure similar to FIG. 5D.

The method of the embodiments of the present disclosure is described in detail above, and the apparatus of the embodiments of the present disclosure will be described in detail below.

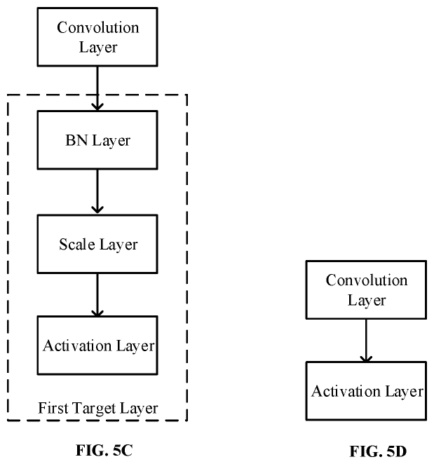

FIG. 6 is a schematic block diagram of a data conversion apparatus 600 according to an embodiment of the present disclosure. The data conversion apparatus 600 includes a base-weight determination module 610 and a weight log-conversion module 620. The base-weight determination module 610 may be configured to determine the base weight value based on the bit width of the log domain of the weight of the first target layer of the neural network and the value of the maximum weight coefficient. The weight log-conversion module 620 may be configured to convert the weight coefficient in the first target layer to the log domain based on the base weight value and the bit width of the log domain of the weight.

In the data conversion apparatus of the present disclosure, the base weight value may be determined based on the bit width of the log domain of the weight and the value of the maximum weight coefficient, and the weight coefficient may be converted to the log domain based on the base weight value and the bit width of the log domain of the weight. As such, the base weight value of the weight coefficient is not based on experience, but is determined based on the bit width of the log domain of the weight and the maximum weight coefficient, which can improve the expression ability of the network and the accuracy of the network.

In some embodiments, the weight log-conversion module 620 converting the weight coefficient in the first target layer to the log domain based on the base weight value and the bit width of the log domain of the weight may include the weight log-conversion module 620 converting the weight coefficient to the log domain based on the base weight value, the bit width of the log domain of the weight, and the value of the weight coefficient.

In some embodiments, the bit width of the log domain of the weight may include a sign bit, and the sign of the weight coefficient in the log domain may be the same as the sign of the weight coefficient in the real domain.

In some embodiments, the data conversion apparatus 600 may further include a real number output module 630. The real number output module 630 may be configured to determine the input feature value of the first target layer after the weight log-conversion module 620 converts the weight coefficient in the first target layer based on the base weight value and the bit width of the log domain of the weight. In addition, the real number output module 630 may be configured to perform the multiply accumulate calculation on the input feature value and the weight coefficient of the log domain through the shift operation to obtain the output value of the first target layer in the real domain.

In some embodiments, the input feature value may be the input feature value in the real domain. The real number output module 630 performing the multiply accumulate calculation on the input feature value and the weight coefficient of the log domain through the shift operation to obtain the output value of the first target layer in the real domain may include real number output module 630 performing the multiply accumulate calculation on the input feature value in the real domain and the weight coefficient of the log domain through the first shift operation to obtain the multiply accumulate value; and performing a second shift operation on the multiply accumulate value to obtain the output value of the first target layer in the real domain.

In some embodiments, the real number output module 630 performing the second shift operation on the multiply accumulate value to obtain the output value of the first target layer in the real domain may include the real number output module 630 performing a shift operation on the multiply accumulate value based on the decimal bit width of the input feature value in the real domain and the decimal bit width of the output value in the real domain to obtain the output value of the first target layer in the real domain.

In some embodiments, the real number output module 630 performing the shift operation on the multiply accumulate value based on the decimal bit width of the input feature value in the real domain and the decimal bit width of the output value in the real domain to obtain the output value of the first target layer in the real domain may include the real number output module 630 performing a shift operation on the multiply accumulate value based on the decimal bit width of the input feature value in the real domain, the decimal bit width of the output value in the real domain, and the base weight value to obtain the output value of the first target layer in the real domain.

In some embodiments, the data conversion apparatus 600 may further include a log output module 640. The log output module 640 may be configured to convert the output value in the real domain to the log domain based on the base output value, the bit width of the log domain of the output value, and the value of the output value in the real domain after the real number output module 630 performs the shift operation on the multiply accumulate value based on the decimal bit width of the input feature value in the real domain, the decimal bit width of the output value in the real domain, and the base weight value to obtain the output value of the first target layer in the real domain.

In some embodiments, the bit width of the log domain of the output value may include a sign bit, and the sign of the output value in the log domain may be the same as the sign of the output value in the real domain.

In some embodiments, the real number output module 630 performing the second shift operation on the multiply accumulate value to obtain the output value of the first target layer in the real domain may include the real number output module 630 performing the shift operation on the multiply accumulate value based on the base weight value and the base output value to obtain the output value of the first target layer in the real domain.

In some embodiments, the log output module 640 may be configured to convert the output value in the real domain to the log domain based on the bit width of the log domain of the output value and the value of the output value in the real domain after the real number output module 630 performs the shift operation on the multiply accumulate value based on the base weight value and the base output value to obtain the output value of the first target layer in the real domain.

In some embodiments, the bit width of the log domain of the output value may include a sign bit, and the sign of the output value in the log domain may be the same as the sign of the output value in the real domain.

In some embodiments, the data conversion apparatus 600 may further include a base-output determination module 650. The base-output determination module 650 may be configured to determine the base output value based on the bit width of the log domain of the output value of the first target layer and the value of the reference output value.

In some embodiments, the data conversion apparatus 600 may further include an output-reference determination module 660. The output-reference determination module 660 may be configured to calculate the maximum output value of each input sample in the first target layer in a plurality of input samples; and select the reference output value from a plurality of maximum output values.

In some embodiments, the output-reference determination module 660 selecting the reference output value from a plurality of maximum output values may include the output-reference determination module 660 sorting the plurality of maximum output values, and selecting the reference output value from the plurality of maximum output values based on the predetermined selection parameter.

In some embodiments, the input feature value may be the input feature value in the log domain. The real number output module 630 performing the multiply accumulate calculation on the input feature value and the weight coefficient of the log domain by using the shift operation to obtain the output value of the first target layer in the real domain may include the real number output module 630 performing the multiply accumulate calculation on the input feature value of the log domain and the weight coefficient of the log domain through the third shift operation to obtain the multiply accumulate value; and, the real number output module 630 performing the fourth shift operation on the multiply accumulate value to obtain the output value of the first target layer in the real domain.

In some embodiments, the real number output module 630 performing the fourth shift operation on the multiply accumulate value to obtain the output value of the first target layer in the real domain may include the real number output module 630 performing a shift operation on the multiply accumulate value based on the base input value, base output value, and base weight value of the input feature value to obtain the output value of the first target layer in the real domain.

In some embodiments, the maximum weight coefficient may be the maximum value of the weight coefficient of the first target layer formed by merging and preprocessing two or more layers of the neural network.

In some embodiments, the data conversion apparatus 600 may further include a preprocessing module 670. The preprocessing module 670 may be configured to perform merge pre-processing on two or more layers of the neural network to obtain the first target layer formed after the merge.

In some embodiments, the maximum output value may be the maximum output value of the first target layer formed by each input sample in the plurality of input samples after merge.

In some embodiments, the preprocessing module 670 performing merge pre-processing on two or more layers of the neural network to obtain the first target layer formed after the merge may include the preprocessing module 670 performing merge preprocessing the convolution layer and the BN layer of the neural network to obtain the first target layer; or, performing merge preprocess the convolution layer and the scale layer of the neural network to obtain the first target layer; or, performing merge preprocessing the convolution layer, BN layer, and the scale layer of the neural network to obtain the first target layer.

In some embodiments, the first target layer may include one or a combined layer of at least two of a convolution layer, a transposed convolution layer, a BN layer, a scale layer, a pooling layer, a fully connected layer, a concatenation layer, an element-wise addition layer.

It should be understood that the base-weight determination module 610, weight log-conversion module 620, real number output module 630, log output module 640, base-output determination module 650, output-reference determination module 660, and the preprocessing module 670 may be implemented by a processor and a memory.

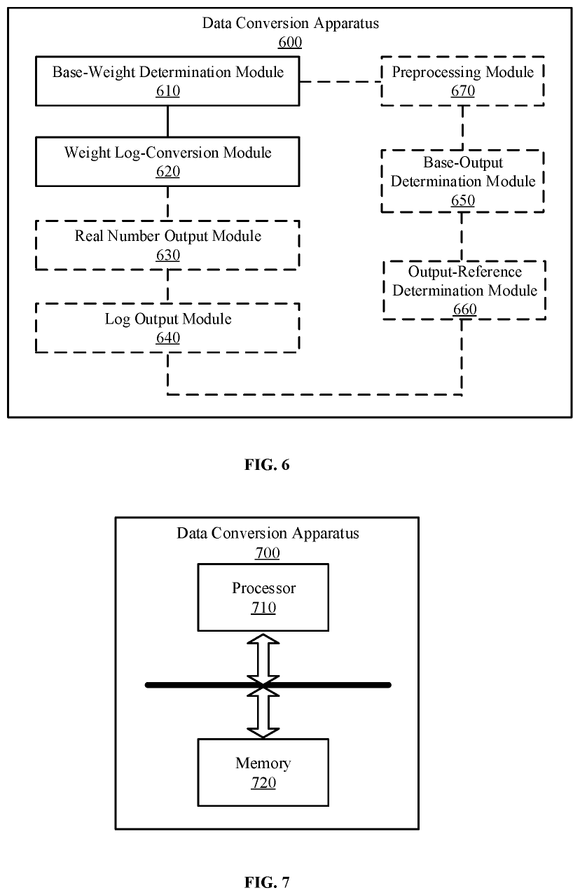

FIG. 7 is a schematic block diagram of a data conversion apparatus 700 according to another embodiment of the present disclosure. The data conversion apparatus 700 shown in FIG. 7 includes a processor 710 and a memory 720. Computer instructions are stored in the memory 720, and when the processor 710 executes the computer instructions, causes the processor 710 to determine the base weight value based on the bit width of the log domain of the weight of the first target layer of the neural network and the value of the maximum weight coefficient; and convert the weight coefficient in the first target layer to the log domain based on the base weight value and the bit width of the log domain of the weight.

In some embodiments, the bit width of the log domain of the weight may include a sign bit, and the sign of the weight coefficient in the log domain may be the same as the sign of the weight coefficient in the real domain.

In some embodiments, after the processor 710 converts the weight coefficient in the first target layer to the log domain based on the base weight value and the bit width of the log domain of the weight, the processor may be further configured to determine the input feature value of the first target layer; and, perform the multiply accumulate calculation on the input feature value and the weight coefficient of the log domain through the shift operation to obtain the output value of the first target layer in the real domain.

In some embodiments, the input feature value may be the input feature value in the real domain. The processor 710 performs the multiply accumulate calculation on the input feature value and the weight coefficient of the log domain through the shift operation to obtain the output value of the first target layer in the real domain may include performing the multiply accumulate calculation on the input feature value in the real domain and the weight coefficient of the log domain through the first shift operation to obtain the multiply accumulate value; and performing a second shift operation on the multiply accumulate value to obtain the output value of the first target layer in the real domain.

In some embodiments, the processor 710 performs the second shift operation on the multiply accumulate value to obtain the output value of the first target layer in the real domain may include performing a shift operation on the multiply accumulate value based on the decimal bit width of the input feature value in the real domain and the decimal bit width of the output value in the real domain to obtain the output value of the first target layer in the real domain.

In some embodiments, the processor 710 performs the shift operation on the multiply accumulate value based on the decimal bit width of the input feature value in the real domain and the decimal bit width of the output value in the real domain to obtain the output value of the first target layer in the real domain may include performing a shift operation on the multiply accumulate value based on the decimal bit width of the input feature value in the real domain, the decimal bit width of the output value in the real domain, and the base weight value to obtain the output value of the first target layer in the real domain

In some embodiments, after the processor 710 performs the shift operation on the multiply accumulate value based on the decimal bit width of the input feature value in the real domain, the decimal bit width of the output value in the real domain, and the base weight value to obtain the output value of the first target layer in the real domain, the processor 710 may be further configured to convert the output value in the real domain to the log domain based on the base output value, the bit width of the log domain of the output value, and the value of the output value in the real domain.

In some embodiments, the bit width of the log domain of the output value may include a sign bit, and the sign of the output value in the log domain may be the same as the sign of the output value in the real domain.

In some embodiments, the processor 710 performs the second shift operation on the multiply accumulate value to obtain the output value of the first target layer in the real domain may include performing the shift operation on the multiply accumulate value based on the base weight value and the base output value to obtain the output value of the first target layer in the real domain.

In some embodiments, after the processor 710 performs the shift operation on the multiply accumulate value based on the base weight value and the base output value to obtain the output value of the first target layer in the real domain, the processor 710 may be further configured to convert the output value in the real domain to the log domain based on the bit width of the log domain of the output value and the value of the output value in the real domain.

In some embodiments, the bit width of the log domain of the output value may include a sign bit, and the sign of the output value in the log domain may be the same as the sign of the output value in the real domain.

In some embodiments, the processor 710 may be further configured to determine the base output value based on the bit width of the log domain of the output value of the first target layer and the value of the reference output value.

In some embodiments, the processor 710 may be further configured to calculate the maximum output value of each input sample in the first target layer in a plurality of input samples; and select the reference output value from a plurality of maximum output values.

In some embodiments, the processor 710 selects the reference output value from the plurality of maximum output values may include sorting the plurality of maximum output values, and selecting the reference output value from the plurality of maximum output values based on the predetermined selection parameter.

In some embodiments, the input feature value may be the input feature value in the log domain. The processor 710 performs the multiply accumulate calculation on the input feature value and the weight coefficient of the log domain by using the shift operation to obtain the output value of the first target layer in the real domain may include performing the multiply accumulate calculation on the input feature value of the log domain and the weight coefficient of the log domain through the third shift operation to obtain the multiply accumulate value; and, performing the fourth shift operation on the multiply accumulate value to obtain the output value of the first target layer in the real domain.

In some embodiments, the processor 710 performs the fourth shift operation on the multiply accumulate value to obtain the output value of the first target layer in the real domain may include performing a shift operation on the multiply accumulate value based on the base input value, base output value, and base weight value of the input feature value to obtain the output value of the first target layer in the real domain.

In some embodiments, the maximum weight coefficient may be the maximum value of the weight coefficient of the first target layer formed by merging and preprocessing two or more layers of the neural network.

In some embodiments, the processor 710 may be further configured to perform merge pre-processing on two or more layers of the neural network to obtain the first target layer formed after the merge.

In some embodiments, the maximum output value may be the maximum output value of the first target layer formed by each input sample in the plurality of input samples after merge.

In some embodiments, the processor 710 performs merge pre-processing on two or more layers of the neural network to obtain the first target layer formed after the merge may include performing merge preprocessing the convolution layer and the BN layer of the neural network to obtain the first target layer; or, performing merge preprocess the convolution layer and the scale layer of the neural network to obtain the first target layer; or, performing merge preprocessing the convolution layer, BN layer, and the scale layer of the neural network to obtain the first target layer.

In some embodiments, the first target layer may include one or a combined layer of at least two of a convolution layer, a transposed convolution layer, a BN layer, a scale layer, a pooling layer, a fully connected layer, a concatenation layer, an element-wise addition layer.

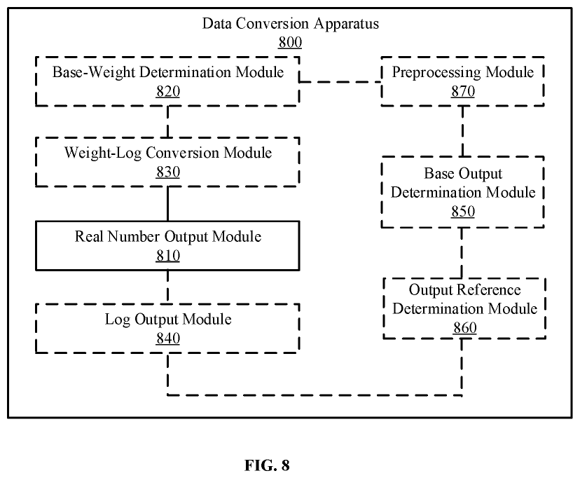

FIG. 8 is a schematic block diagram of a data conversion apparatus 800 according to another embodiment of the present disclosure. The data conversion apparatus 800 includes a real number output module 810. The real number output module 810 may be configured to determine the input feature value of the first target layer of the neural network; and perform the multiply accumulate calculation on the input feature value and the bit width of the log domain of the weight by using the shift operation to obtained the output value of the first target layer in the real domain.

The data conversion apparatus provided in the embodiments of the present disclosure can perform simple addition and shift operations on the input feature value and the weight coefficient of the log domain to realize the multiply accumulate operation, which does not require a multiplier and can reduce the equipment costs.

In some embodiments, the input feature value may be the input feature value in the real domain. The real number output module 810 performing the multiply accumulate calculation on the input feature value and the weight coefficient of the log domain through the shift operation to obtain the output value of the first target layer in the real domain may include the real number output module 810 performing the multiply accumulate calculation on the input feature value in the real domain and the weight coefficient of the log domain through the first shift operation to obtain the multiply accumulate value; and performing a second shift operation on the multiply accumulate value to obtain the output value of the first target layer in the real domain.

In some embodiments, the real number output module 810 performing the second shift operation on the multiply accumulate value to obtain the output value of the first target layer in the real domain may include the real number output module 810 performing a shift operation on the multiply accumulate value based on the decimal bit width of the input feature value in the real domain and the decimal bit width of the output value in the real domain to obtain the output value of the first target layer in the real domain.

In some embodiments, the real number output module 810 performing the shift operation on the multiply accumulate value based on the decimal bit width of the input feature value in the real domain and the decimal bit width of the output value in the real domain to obtain the output value of the first target layer in the real domain may include the real number output module 810 performing a shift operation on the multiply accumulate value based on the decimal bit width of the input feature value in the real domain, the decimal bit width of the output value in the real domain, and the base weight value to obtain the output value of the first target layer in the real domain.

In some embodiments, the data conversion apparatus 800 may further include a log output module 840. The log output module 840 may be configured to convert the output value in the real domain to the log domain based on the base output value, the bit width of the log domain of the output value, and the value of the output value in the real domain after the real number output module 810 performs the shift operation on the multiply accumulate value based on the decimal bit width of the input feature value in the real domain, the decimal bit width of the output value in the real domain, and the base weight value to obtain the output value of the first target layer in the real domain.

In some embodiments, the bit width of the log domain of the output value may include a sign bit, and the sign of the output value in the log domain may be the same as the sign of the output value in the real domain.

In some embodiments, the real number output module 810 performing the shift operation on the multiply accumulate value to obtain the output value of the first target layer in the real domain may include the real number output module 810 performing the shift operation on the multiply accumulate value based on the base weight value and the base output value to obtain the output value of the first target layer in the real domain.

In some embodiments, the log output module 840 may be configured to convert the output value in the real domain to the log domain based on the bit width of the log domain of the output value and the value of the output value in the real domain after the real number output module 810 performs the shift operation on the multiply accumulate value based on the base weight value and the base output value to obtain the output value of the first target layer in the real domain.

In some embodiments, the bit width of the log domain of the output value may include a sign bit, and the sign of the output value in the log domain may be the same as the sign of the output value in the real domain.

In some embodiments, the data conversion apparatus 800 may further include a reference determination module 860. The reference determination module 860 may be configured to calculate the maximum output value of each input sample in the first target layer in a plurality of input samples; and select the reference output value from a plurality of maximum output values.

In some embodiments, the reference determination module 860 selecting the reference output value from a plurality of maximum output values may include the reference determination module 860 sorting the plurality of maximum output values, and selecting the reference output value from the plurality of maximum output values based on the predetermined selection parameter.

In some embodiments, the input feature value may be the input feature value in the log domain. The real number output module 810 performing the multiply accumulate calculation on the input feature value and the weight coefficient of the log domain by using the shift operation to obtain the output value of the first target layer in the real domain may include the real number output module 810 performing the multiply accumulate calculation on the input feature value of the log domain and the weight coefficient of the log domain through the third shift operation to obtain the multiply accumulate value; and, the real number output module 810 performing the fourth shift operation on the multiply accumulate value to obtain the output value of the first target layer in the real domain.

In some embodiments, the real number output module 810 performing the fourth shift operation on the multiply accumulate value to obtain the output value of the first target layer in the real domain may include the real number output module 810 performing a shift operation on the multiply accumulate value based on the base input value, base output value, and base weight value of the input feature value to obtain the output value of the first target layer in the real domain.

In some embodiments, the data conversion apparatus 800 may further include a base-weight determination module 820 and a weight log-conversion module 830. The base-weight determination module 820 may be configured to determine the base weight value based on the bit width of the log domain of the weight of the first target layer and the value of the maximum weight coefficient. The weight log-conversion module 830 may be configured to convert the weight coefficient of the real domain in the first target layer to the log domain based on the base weight value and the bit width of the log domain of the weight to obtain the weight coefficient of the log domain.

In some embodiments, the weight log-conversion module 830 converting the weight coefficient of the real domain in the first target layer to the log domain based on the base weight value and the bit width of the log domain of the weight to obtain the weight coefficient of the log domain may include the weight log-conversion module 830 converting the weight coefficient of the real domain to the log domain based on the base weight value, the bit width of the log domain of the weight, and the value of the weight coefficient to obtain the weight coefficient of the log domain.

In some embodiments, the bit width of the log domain of the weight may include a sign bit, and the sign bit of the weight coefficient in the log domain may be the same as the sign of the weight coefficient in the real domain.

In some embodiments, the maximum weight coefficient may be the maximum value of the weight coefficient of the first target layer formed by merging and preprocessing two or more layers of the neural network.

In some embodiments, the data conversion apparatus 800 may further include a preprocessing module 870. The preprocessing module 870 may be configured to perform merge pre-processing on two or more layers of the neural network to obtain the first target layer formed after the merge

In some embodiments, the maximum output value may be the maximum output value of the first target layer formed by each input sample in the plurality of input samples after merge.

In some embodiments, the preprocessing module 870 performing merge pre-processing on two or more layers of the neural network to obtain the first target layer formed after the merge may include the preprocessing module 870 performing merge preprocessing the convolution layer and the BN layer of the neural network to obtain the first target layer; or, performing merge preprocess the convolution layer and the scale layer of the neural network to obtain the first target layer; or, performing merge preprocessing the convolution layer, BN layer, and the scale layer of the neural network to obtain the first target layer.

In some embodiments, the first target layer may include one or a combined layer of at least two of a convolution layer, a transposed convolution layer, a BN layer, a scale layer, a pooling layer, a fully connected layer, a concatenation layer, an element-wise addition layer.

It should be understood that the real number output module 810, base-weight determination module 820, weight-log conversion module 830, log output module 840, base output determination module 850, the output reference determination module 860, and the preprocessing module 870 may be implemented by a processor and a memory.

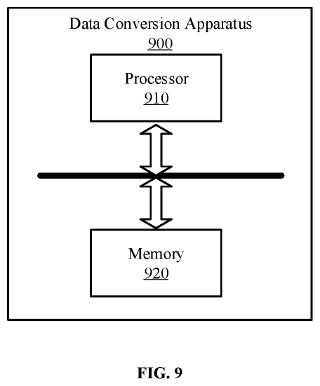

FIG. 9 is a schematic block diagram of a data conversion apparatus 900 according to another embodiment of the present disclosure. The data conversion apparatus 900 shown in FIG. 9 includes a processor 910 and a memory 920. Computer instructions are stored in the memory 920, and when the processor 910 executes the computer instructions, causes the processor 910 to determine the input feature value of the first target layer of the neural network; and perform the multiply accumulate calculation on the input feature value and the bit width of the log domain of the weight by using the shift operation to obtained the output value of the first target layer in the real domain.

In some embodiments, the input feature value may be the input feature value in the real domain. The processor 910 performs the multiply accumulate calculation on the input feature value and the weight coefficient of the log domain through the shift operation to obtain the output value of the first target layer in the real domain may include performing the multiply accumulate calculation on the input feature value in the real domain and the weight coefficient of the log domain through the first shift operation to obtain the multiply accumulate value; and performing a second shift operation on the multiply accumulate value to obtain the output value of the first target layer in the real domain.

In some embodiments, the processor 910 performs the second shift operation on the multiply accumulate value to obtain the output value of the first target layer in the real domain may include performing a shift operation on the multiply accumulate value based on the decimal bit width of the input feature value in the real domain and the decimal bit width of the output value in the real domain to obtain the output value of the first target layer in the real domain.

In some embodiments, the processor 910 performs the shift operation on the multiply accumulate value based on the decimal bit width of the input feature value in the real domain and the decimal bit width of the output value in the real domain to obtain the output value of the first target layer in the real domain may include performing a shift operation on the multiply accumulate value based on the decimal bit width of the input feature value in the real domain, the decimal bit width of the output value in the real domain, and the base weight value to obtain the output value of the first target layer in the real domain.

In some embodiments, the processor 910 may be further configured to convert the output value in the real domain to the log domain based on the base output value, the bit width of the log domain of the output value, and the value of the output value in the real domain after the processor 910 performs the shift operation on the multiply accumulate value based on the decimal bit width of the input feature value in the real domain, the decimal bit width of the output value in the real domain, and the base weight value to obtain the output value of the first target layer in the real domain.

In some embodiments, the bit width of the log domain of the output value may include a sign bit, and the sign of the output value in the log domain may be the same as the sign of the output value in the real domain.

In some embodiments, the processor 910 performs the second shift operation on the multiply accumulate value to obtain the output value of the first target layer in the real domain may include performing the shift operation on the multiply accumulate value based on the base weight value and the base output value to obtain the output value of the first target layer in the real domain.

In some embodiments, the processor 910 may be further configured to convert the output value in the real domain to the log domain based on the bit width of the log domain of the output value and the value of the output value in the real domain after the processor 910 performs the shift operation on the multiply accumulate value based on the base weight value and the base output value to obtain the output value of the first target layer in the real domain.

In some embodiments, the bit width of the log domain of the output value may include a sign bit, and the sign of the output value in the log domain may be the same as the sign of the output value in the real domain.

In some embodiments, the processor 910 may be further configured to determine the base output value based on the bit width of the log domain of the output value of the first target layer and the value of the reference output value.

In some embodiments, the processor 910 may be further configured to calculate the maximum output value of each input sample in the first target layer in a plurality of input samples; and select the reference output value from a plurality of maximum output values.

In some embodiments, the processor 910 selects the reference output value from the plurality of maximum output values may include sorting the plurality of maximum output values, and selecting the reference output value from the plurality of maximum output values based on the predetermined selection parameter.

In some embodiments, the input feature value may be the input feature value in the log domain. The processor 910 performs the multiply accumulate calculation on the input feature value and the weight coefficient of the log domain by using the shift operation to obtain the output value of the first target layer in the real domain may include performing the multiply accumulate calculation on the input feature value of the log domain and the weight coefficient of the log domain through the third shift operation to obtain the multiply accumulate value; and, performing the fourth shift operation on the multiply accumulate value to obtain the output value of the first target layer in the real domain.

In some embodiments, the processor 910 performs the fourth shift operation on the multiply accumulate value to obtain the output value of the first target layer in the real domain may include performing a shift operation on the multiply accumulate value based on the base input value, base output value, and base weight value of the input feature value to obtain the output value of the first target layer in the real domain.

In some embodiments, the processor 910 may be further configured to determine the base weight value based on the bit width of the log domain of the weight of the first target layer and the value of the maximum weight coefficient; and, convert the weight coefficient of the real domain in the first target layer to the log domain based on the base weight value and the bit width of the log domain of the weight to obtain the weight coefficient of the log domain.

In some embodiments, the processor 910 converts the weight coefficient of the real domain in the first target layer to the log domain based on the base weight value and the bit width of the log domain of the weight to obtain the weight coefficient of the log domain may include converting the weight coefficient of the real domain to the log domain based on the base weight value, the bit width of the log domain of the weight, and the value of the weight coefficient to obtain the weight coefficient of the log domain.

In some embodiments, the bit width of the log domain of the weight may include a sign bit, and the sign bit of the weight coefficient in the log domain may be the same as the sign of the weight coefficient in the real domain.

In some embodiments, the maximum weight coefficient may be the maximum value of the weight coefficient of the first target layer formed by merging and preprocessing two or more layers of the neural network.

In some embodiments, the processor 910 may be further configured to perform merge pre-processing on two or more layers of the neural network to obtain the first target layer formed after the merge.

In some embodiments, the maximum output value may be the maximum output value of the first target layer formed by each input sample in the plurality of input samples after merge.

In some embodiments, the processor 910 performs merge pre-processing on two or more layers of the neural network to obtain the first target layer formed after the merge may include performing merge preprocessing the convolution layer and the BN layer of the neural network to obtain the first target layer; or, performing merge preprocess the convolution layer and the scale layer of the neural network to obtain the first target layer; or, performing merge preprocessing the convolution layer, BN layer, and the scale layer of the neural network to obtain the first target layer.

In some embodiments, the first target layer may include one or a combined layer of at least two of a convolution layer, a transposed convolution layer, a BN layer, a scale layer, a pooling layer, a fully connected layer, a concatenation layer, an element-wise addition layer.

It should be understood that the apparatus of the embodiments of the present disclosure may be implemented based on a memory and a processor. The memory may be used to store instructions for executing the method of the embodiments of the present disclosure, and the processor may be used to execute the above instructions to cause the apparatus to execute the method of the embodiments of the present disclosure.

In various embodiments of the present disclosure, the processor may be a central processing unit (CPU), a general-purpose processor, a digital signal processor (DSP), an application specific integrated circuit (ASIC), a field programmable gate array (FPGA) or another programmable logic device, a discrete gate/transistor logic device, or a discrete hardware component. A general-purpose processor may be a microprocessor or any conventional processor.

In various embodiments of the present disclosure, the memory may be a volatile memory, a non-volatile memory, or a combination thereof. The non-volatile memory may be a read-only memory (ROM), a programmable read-only memory (PROM), an erasable programmable read-only memory (EPROM), an electrically erasable programmable read-only memory (EEPROM), or a flash memory. The volatile memory may be a random access memory (RAM), and may be used as an external cache. The RAM may be a static random access memory (SRAM), a dynamic random access memory (DRAM), a synchronous dynamic random access memory (SDRAM), a double data rate synchronous dynamic random access memory (DDR SDRAM), an enhanced synchronous dynamic random access memory (ESDRAM), a synchlink dynamic random access memory (SLDRAM), or a direct rambus random access memory (DRRAM). The above random access memories are used as examples to illustrate the present disclosure and should not limit the scopes of the present disclosure.

In one embodiment, when the processor is a general-purpose processor, a DSP, a ASIC, a FPGA or another programmable logic device, a discrete gate/transistor logic device, or a discrete hardware component, the memory (or the memory module) may be integrated in the processor.

The present disclosure also provides a computer-readable storage medium. The storage medium may be configured to store instructions. When the instructions are executed by the computer, the computer may perform above motion estimation methods provided by various embodiments of the present disclosure.

The present disclosure also provides a computing device including a computer-readable storage medium described above.

The present disclosure may be applied to the aerial vehicle field, especially the unmanned aerial vehicle field.

It should be understood that the division of the circuits, sub-circuits, and sub-units in the embodiments of the present disclosure is only exemplary. Those of ordinary skill in the art will appreciate that the exemplary circuits, sub-circuits, and sub-units described in the embodiments of the present disclosure can be split or combined again.

All or some embodiments of the present disclosure may be implemented in software, hardware, firmware, or combinations thereof. When being implemented in software, all or some embodiments of the present disclosure may be implemented in form of a computer program product. The computer program product includes one or more computer instructions. When being loaded and executed by a computer, the computer program instructions perform all or some steps or functions according to the flowcharts in the embodiments of the present disclosure. The computer may be a general-purpose computer, a special-purpose computer, a computer network, or other programmable devices. The computer program instructions may be stored in a computer readable storage medium or transferred from one computer readable storage medium to anther computer readable storage medium. For example, the computer program instructions may be transferred from one website, one computer, one server, or one data center to another web site, another computer, another server, or another data center through wired (e.g., coaxial cable, optical fiber, digital subscriber line) or wireless (e.g., infrared, wireless, microwave, etc.) communication. The computer readable storage medium may be any suitable medium accessible by a computer or a data storage device including one or more suitable media, such as a server or a data center. The suitable medium may be a magnetic medium (e.g., a floppy disk, a hard disk, a magnetic tape), an optical medium (e.g., a DVD disk), or a semiconductor medium (e.g., an SSD drive).

It should be understood that that the embodiments of the present disclosure are described by taking the total bit width of 16 bits as an example, and the embodiments of the present disclosure may be applied to other bit widths.

Reference throughout this specification to “one embodiment” or “an embodiment” means that a particular feature, structure, or characteristic associated with the embodiment is included in at least one embodiment of the present disclosure. Hence, the appearance of “In some embodiments” or “in an embodiment” in various places throughout the specification is not necessarily referring to the same embodiment. Moreover, these specific features, structures, or characteristics can be combined in one or more embodiments in any suitable manner.

In various embodiments of the present disclosure, the magnitude of the sequence numbers of the above processes does not mean the order of the execution, and the execution sequence of each process should be determined by its function and internal logic, and should not be limited by the implementation process of the embodiments consistent with the present disclosure.

In the embodiments of the present disclosure, “B corresponds to A” means that B is associated with A, and according to A, B can be determined. However, it should also be understood that, determining B according to A does not mean that B is only determined according to A. B can be determined according to A and/or other information.

The terms “and/or” used herein is merely an association describing an associated object, indicating that there may be three relationships. For example, A and/or B may indicate three cases, such as A exists alone, A and B both exist, and B exists alone. Moreover, the symbol “/” in the text generally indicates that the related objects in the context have an “or” relationship.

Those of ordinary skill in the art will appreciate that the example elements and algorithm steps described above can be implemented in electronic hardware, or in a combination of computer software and electronic hardware. Whether these functions are implemented in hardware or software depends on the specific application and design constraints of the technical solution. One of ordinary skill in the art can use different methods to implement the described functions for different application scenarios, but such implementations should not be considered as beyond the scope of the present disclosure.

For simplification purposes, detailed descriptions of the operations of example systems, devices, and units may be omitted, and references can be made to the descriptions of the example methods.

The disclosed systems, apparatuses, and methods may be implemented in other manners not described here. For example, the devices described above are merely illustrative. For example, the division of units may only be a logical function division, and there may be other ways of dividing the units. For example, multiple units or components may be combined or may be integrated into another system, or some features may be ignored, or not executed. Further, the coupling or direct coupling or communication connection shown or discussed may include a direct connection or an indirect connection or communication connection through one or more interfaces, devices, or units, which may be electrical, mechanical, or in other form.

The units described as separate components may or may not be physically separate, and a component shown as a unit may or may not be a physical unit. That is, the units may be located in one place or may be distributed over a plurality of network elements. Some or all of the components may be selected according to the actual needs to achieve the object of the present disclosure.

In addition, the functional units in the various embodiments of the present disclosure may be integrated in one processing unit, or each unit may be an individual physically unit, or two or more units may be integrated in one unit.

The foregoing descriptions are merely some implementation manners of the present disclosure, but the scope of the present disclosure is not limited thereto. Without departing from the spirit and principles of the present disclosure, any modifications, equivalent substitutions, and improvements, etc. shall fall within the scope of the present disclosure. Thus, the scope of invention should be determined by the appended claims.

What is claimed is:

1. A data conversion method, comprising:
determining a base weight value based on a bit width of a log domain of a weight and a value of a maximum weight coefficient of a first target layer of a neural network; and
converting a weight coefficient in the first target layer to the log domain based on the base weight value and the bit width of the log domain of the weight.

2. The method of claim 1, wherein converting the weight coefficient in the first target layer to the log domain based on the base weight value and the bit width of the log domain of the weight includes:
converting the weight coefficient to the log domain based on the base weight value, the bit width of the log domain of the weight, and a value of the weight coefficient.

3. The method of claim 2, wherein:
the bit width of the log domain of the weight includes a sign bit, and the sign bit of the weight coefficient in the log domain is consistent with the sign of the weight coefficient in a real domain.

4. The method of claim 1, wherein after converting the weight coefficient in the first target layer to the log domain based on the base weight value and the bit width of the log domain of the weight, the method further comprising:
determining an input feature value of the first target layer; and
performing a multiply accumulate calculation on the input feature value and the weight coefficient of the log domain through a shift operation to obtain an output value of the first target layer in the real domain.

5. The method of claim 4, wherein the input feature value is an input feature value in the real domain, and performing the multiply accumulate calculation on the input feature value and the weight coefficient of the log domain through the shift operation to obtain the output value of the first target layer in the real domain includes:
performing the multiply accumulate calculation on the input feature value in the real domain and the weight coefficient in the log domain through a first shift operation to obtain a multiply accumulate value; and
performing a second shift operation on the multiply accumulate value to obtain the output value of the first target layer in the real domain.

6. The method of claim 5, wherein performing the second shift operation on the multiply accumulate value to obtain the output value of the first target layer in the real domain includes:
performing the shift operation on the multiply accumulate value based on a decimal bit width of the input feature value in the real domain and a decimal bit width of the output value in the real domain to obtain the output value of the first target layer in the real domain.

7. The method of claim 6, wherein performing the shift operation on the multiply accumulate value based on a decimal bit width of the input feature value in the real domain and a decimal bit width of the output value in the real domain to obtain the output value of the first target layer in the real domain includes:
performing the shift operation on the multiply accumulate value based on the decimal bit width of the input feature value in the real domain, the decimal bit width of the output value in the real domain, and the base weight value to obtain the output value of the first target layer in the real domain.

8. The method of claim 7, wherein after performing the shift operation on the multiply accumulate value based on the decimal bit width of the input feature value in the real domain, the decimal bit width of the output value in the real domain, and the base weight value to obtain the output value of the first target layer in the real domain, further comprising:
converting the output value in the real domain to the log domain based on a base output value, the bit width of the log domain of the output value, and a value of the output value in the real domain.

9. The method of claim 5, wherein performing the second shift operation on the multiply accumulate value to obtain the output value of the first target layer in the real domain includes:
performing the shift operation on the multiply accumulate value based on the base weight value and the base output value to obtain the output value of the first target layer in the real domain.

10. The method of claim 9, wherein after performing the shift operation on the multiply accumulate value based on the base weight value and the base output value to obtain the output value of the first target layer in the real domain, further comprising:
converting the output value in the real domain to the log domain based on the bit width of the log domain of the output value and the value of the output value in the real domain.

11. The method of claim 10, wherein:
the bit width of the log domain of the output value includes a sign bit, and the sign bit of the output value in the log domain is consistent with the sign of the output value in the real domain.

12. The method of claim 8, further comprising:
determining the base output value based on the bit width of the log domain of the output value of the first target layer and a reference output value.

13. The method of claim 12, further comprising:
calculating a maximum output value of each input sample in the first target layer in a plurality of input samples; and
selecting the reference output value from a plurality of maximum output values.

14. The method of claim 13, wherein selecting the reference output value from the plurality of maximum output values includes:
sorting the plurality of maximum output values, and selecting the reference output value from the plurality of maximum output values based on a predetermined selection parameter.

15. The method of claim 4, wherein the input value is an input feature value in the log domain, and performing the multiply accumulate calculation on the input feature value and the weight coefficient of the log domain through the shift operation to obtain the output value of the first target layer in the real domain includes:
performing the multiply accumulate calculation on the input feature value of the log domain and the weight coefficient of the log domain to obtain the multiply accumulate value; and
performing a fourth shift operation on the multiply accumulate value to obtain the output value of the first target layer in the real domain.

16. The method of claim 15, wherein performing the fourth shift operation on the multiply accumulate value to obtain the output value of the first target layer in the real domain includes:
performing the shift operation on the multiply accumulate value based on a base input value, the base output value, and the base weight value of the input feature value of the log domain to obtain the output value of the first target layer in the real domain.

17. The method of claim 1, wherein:
the maximum weight coefficient is the maximum value of the weight coefficient of the first target layer formed by a merge preprocessing on two or more layers of the neural network.

18. The method of claim 1, further comprising:
performing the merge preprocessing on two or more layers of the neural network to obtain the first target layer formed after merging.

19. The method of claim 18, wherein performing the merge preprocessing on two or more layers of the neural network to obtain the first target layer formed after merging includes:
performing the merge preprocessing on a convolution layer and a batch normalization (BN) layer of the neural network to obtain the first target layer; or,
performing the merge preprocessing on the convolution layer and a scale layer of the neural network to obtain the first target layer; or,
performing the merge preprocessing on the convolution layer, the BN layer, and the scale layer of the neural network to obtain the first target layer.

20. A data conversion apparatus, comprising:
a processor; and
a memory storing program instructions that, when executed by the processor, causing the processor to:
determine a base weight value based on a bit width of a log domain of a weight and a value a maximum weight coefficient of a first target layer of a neural network; and
convert the weight coefficient in the first target layer to the log domain based on the base weight value and the bit width of the log domain of the weight.
